(19) United States
(12) Patent Application Publication
(10) Pub. No.: US 2010/0186673 A1
(43) Pub. Date: Jul. 29, 2010

(54) VAPORIZER, MATERIAL GAS SUPPLY SYSTEM INCLUDING VAPORIZER AND FILM FORMING APPARATUS USING SUCH SYSTEM

(75) Inventors: Sumi TANAKA, Nirasaki-shi (JP); Tomohito KOMATSU, Nirasaki-shi (JP); Munehisa FUTAMURA, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/710,890

(22) Filed: Feb. 23, 2010

Related U.S. Application Data
(63) Continuation of application No. PCT/JP2008/065025, filed on Aug. 22, 2008.

(30) Foreign Application Priority Data
Aug. 23, 2007 (JP) 2007-217640

(51) Int. Cl. H01L 21/46

(52) U.S. Cl. 118/726; 257/E21.482

(57) ABSTRACT

A vaporizer having a simple structure with improved thermal efficiency is provided. A vaporizer includes a nozzle unit for jetting a liquid material in a mist state, a vaporizing unit having vaporizing paths which vaporize the material mist and form a material gas, and an ejection unit for sending the material gas to the subsequent stage. The vaporizing unit includes a vaporizing unit main body having the vaporizing paths, a main body container containing the vaporizing unit main body, a heater for heating the material mist passing through the vaporizing paths, and connecting members arranged on both end sections of the main body container. The vaporizing unit main body and the main body container are formed of a material having thermal conductivity higher than that of the material of the connecting members. The end sections of the main body container and the connecting members are bonded by explosion bonding.

This application is a Continuation Application of PCT International Application No. PCT/JP2008/065025 filed on Aug. 22, 2008, which designated the United States.

### FIELD OF THE INVENTION

The present invention relates to a film forming apparatus for forming a thin film on a surface of a target object such as a semiconductor wafer, a material gas supply system for supplying a material gas to the film forming apparatus, a vaporizer used in the supply system and a vaporizing unit included in the vaporizer.

### BACKGROUND OF THE INVENTION

In general, various processes such as a film forming process and a pattern etching process are repeatedly performed on a semiconductor wafer to manufacture semiconductor devices. In such processes, a film forming technique is required to be further improved along with the trend of high-density and high-integration semiconductor devices. For example, a barrier film, a dielectric film and an insulating film and the like, which are used in forming a capacitor or a gate in the devices, are required to be thinner.

Typically, a thin film containing a metal element is formed by using an organic or inorganic material containing the metal element, wherein the material is mostly liquid.

In order to supply a liquid material to a film forming apparatus, for example, a bubbling method and a force-feeding method are employed. In the bubbling method (see, e.g., Japanese Patent Laid-open Publication No. 2004-079985), an inert gas is introduced into a material tank storing a liquid material to cause bubbling, and the liquid material is vaporized by bubbling to be supplied to the film forming apparatus. Further, in the force-feeding method (see, e.g., Japanese Patent Laid-open Publications Nos. 2004-207713 and 2004-296614), a liquid material in a material tank is force-fed by a pressurized gas while its flow rate is controlled, and the liquid material is vaporized in a vaporizer to be supplied to the film forming apparatus.

In the bubbling method, it is difficult to accurately control a flow rate of the liquid material bubbled by an inert gas. Meanwhile, in the force-feeding method, the flow rate can be relatively accurately controlled. Thus, the force-feeding method is widely used.

As described above, in the force-feeding method, a liquid material in a material tank is force-fed by a pressurized gas while its flow rate is controlled. In this case, the flow rate of the liquid material is controlled by using a liquid flowmeter and a flow rate control valve installed in a liquid material transfer line. Specifically, the flow rate is measured by the liquid flowmeter and the flow rate control valve is controlled based on the measurement values. Further, the force-fed liquid material is vaporized by a vaporizer provided in a force-feeding path to produce a material gas, and the material gas is supplied to the film forming apparatus.

However, in a case of supplying a material gas by using the force-feeding method, the material path or the vaporizer is generally formed of stainless steel. Further, the vaporizer or the material path is provided with a heater, e.g., a tape heater, to accelerate the vaporization of the liquid material or prevent re-liquefaction of the vaporized liquid material.

The vaporizer formed of stainless steel has relatively low thermal conductivity. Accordingly, the heat cannot be efficiently supplied from the heater to an inner heating surface of the vaporizer for vaporizing the liquid material.

It may lead to low thermal responsiveness and insufficient heat supply. Accordingly, it results in a problem that a sufficient amount of material gas cannot be produced even though the liquid material is atomized.

In order to solve the problem, it can be considered that the vaporizer is configured to include a heating part for vaporization which is made of aluminum having good thermal conductivity wherein the aluminum part and a stainless steel part are fastened to each other via, e.g., bolts while a seal member such as an O ring is interposed therebetween. However, in this configuration, misalignment between the two parts may occur due to a thermal expansion difference between the two parts to thereby cause leakage of the material gas. Thus, this configuration cannot actually be used.

It can also be considered to set the temperature of the heater to a high level. However, in this case, the temperature of the material becomes locally excessively high, and the material may be thermally decomposed. Further, in order to compensate for low thermal conductivity, a heater may be provided inside the vaporizer. However, in this case, the entire structure becomes complicated, thereby increasing the manufacturing cost.

### SUMMARY OF THE INVENTION

The present invention has been devised in order to solve the problems described above. It is an object of the present invention to provide a vaporizing unit having a simple structure with improved thermal efficiency, a vaporizer including the vaporizing unit, a material gas supply system including the vaporizer, and a film forming apparatus including the material gas supply system.

In accordance with an aspect of the present invention, there is provided a vaporizer including: a nozzle unit for spraying a liquid material supplied thereto in a mist state with a carrier gas to produce a material mist; a vaporizing unit connected to the nozzle unit and having a plurality of vaporizing paths through which the material mist passes to heat and vaporize the material mist to produce a material gas; and an ejection unit connected to the vaporizing unit to eject the material gas to a subsequent stage, wherein the vaporizing unit includes: a vaporizing unit main body in which the vaporizing paths are formed; a main body container containing the vaporizing unit main body, both end sections of the main body container being extended further than the vaporizing unit main body; a heater for heating the material mist passing through the vaporizing paths; and connecting members provided at the both end sections of the main body container to connect the vaporizing unit with the nozzle unit and the ejection unit, wherein the vaporizing unit main body and the main body container are formed of a material different from a material of the connecting members, where the material of the vaporizing unit main body and the main body container has thermal conductivity higher than that of the connecting members, and wherein the end sections of the main body container are bonded to the connecting members by explosion bonding.

The main body container and the vaporizing unit main body may be formed as a single body by machining.

A length of each of the end sections of the main body container extended from the vaporizing unit main body may be set such that a thermal stress applied to each of the end sections is equal to or less than a fatigue limit of the material of the main body container at an allowable maximum temperature. In this case, the allowable maximum temperature may be 300° C. and the fatigue limit may be twenty percent (20%) of a proof stress of the material of the main body container.

The material of the vaporizing unit main body and the main body container may be one material selected from a group consisting of aluminum, an aluminum alloy and nickel, and the material of the connecting members may be stainless steel or a Ni alloy such as Hastelloy (registered trademark).

A material of the nozzle unit and the ejection unit may be stainless steel or a Ni alloy such as Hastelloy (registered trademark). The liquid material may be one material selected from a group consisting of pentaethoxy tantalum (PET), a metal liquid material for forming a PZT film (an oxide film including Pb, Zr and Ti), a BST film (an oxide film including Ba, Sr and Ti) or the like, Cu(EDMDD)₂, tetraethoxysilane (TEOS), copper hexafluoroacetylacetonate trimethylvinylsilane (Cu(hfac)TMVS), trimethyl aluminum (TMA), tert-butylimidotris(diethylamido)tantalum (TBTDET), titanium tetrachloride (TiCl₄), tetramethylsilane (TMS), and tetrakisethoxy hafnium (TEH).

In accordance with another aspect of the present invention, there is provided a material gas supply system for supplying a material gas to a gas using system, including: a liquid material tank storing therein a liquid material; a material path whose one end is connected to the liquid material tank and whose other end is connected to the gas using system; a force-feed unit provided to the liquid material tank to force-feed the liquid material to the material path with a pressurized gas; and the vaporizer described above, the vaporizer being installed in the material path to vaporize the liquid material to produce a material gas.

In accordance with still another aspect of the present invention, there is provided a film forming apparatus for performing a film forming process on a target object, including: a vacuum evacuable processing chamber; a holding unit for holding the target object in the processing chamber; a heating unit for heating the target object; a gas inlet member for introducing a gas into the processing chamber; and the material gas supply system described above and connected to the gas inlet member.

In accordance with still another aspect of the present invention, there is provided a vaporizing unit for vaporizing a material mist to produce a material gas, including: a vaporizing unit main body in which the vaporizing paths are formed, the material mist passing through the vaporizing paths, a main body container containing the vaporizing unit main body, a heater for heating the material mist passing through the vaporizing paths, connecting members provided at both end sections of the main body container to connect the vaporizing unit with a component provided at upstream or downstream side of the vaporizing unit, wherein the vaporizing unit main body and the main body container are formed of a material different from a material of the connecting members, where the material of the vaporizing unit main body and the main body container has thermal conductivity higher than that of the connecting members, and wherein the end sections of the main body container are bonded to the connecting members by explosion bonding.

The main body container and the vaporizing unit main body may be formed as a single body by machining.

The both end sections of the main body container may be extended further than the vaporizing unit main body, and a length of each of the end sections of the main body container extended from the vaporizing unit main body may be set such that a thermal stress applied to each of the end sections is equal to or less than a fatigue limit of the material of the main body container at an allowable maximum temperature. In this case, the allowable maximum temperature may be 300° C. and the fatigue limit may be twenty percent (20%) of a proof stress of the material of the main body container.

The material of the vaporizing unit main body and the main body container may be one material selected from a group consisting of aluminum, an aluminum alloy and nickel, and the material of the connecting members may be stainless steel or a Ni alloy such as Hastelloy (registered trademark).

A material of the component provided at the upstream or downstream side of the vaporizing unit may be stainless steel or a Ni alloy such as Hastelloy (registered trademark).

In accordance with the present invention, a material having high thermal conductivity such as aluminum is used as one of constituent materials and is boned to a different material by explosion bonding. Accordingly, it is possible to provide the vaporizer having a simple structure with improved thermal efficiency. Thus, it is possible to supply a large amount of material gas without increasing the size of the vaporizer.

### BRIEF DESCRIPTION OF THE DRAWINGS

FIG. 1 illustrates a configuration of a film forming apparatus using a material gas supply system having a vaporizer in accordance with an embodiment of the present invention.

FIG. 2 is a cross sectional view of the vaporizer.

FIG. 3 is an exploded cross sectional view of the vaporizer.

FIG. 4 is an exploded perspective view of a vaporizing unit of the vaporizer.

FIG. 5 is an enlarged view of a portion A of FIG. 3.

FIG. 6 is a graph showing a relationship between the thermal stress and a length H of the end portion of the main body container extended from the end portion of the vaporizing unit main body.

### DETAILED DESCRIPTION OF THE EMBODIMENTS

Hereinafter, an embodiment of the present invention will be described with reference to the accompanying drawings. In this embodiment, pentaethoxy tantalum (Ta(OC₂H₂)₅) (hereinafter, also referred to as “PET”) is used as a liquid material and 0₂ gas is used as an oxidizing gas to form a tantalum oxide film on a target object.

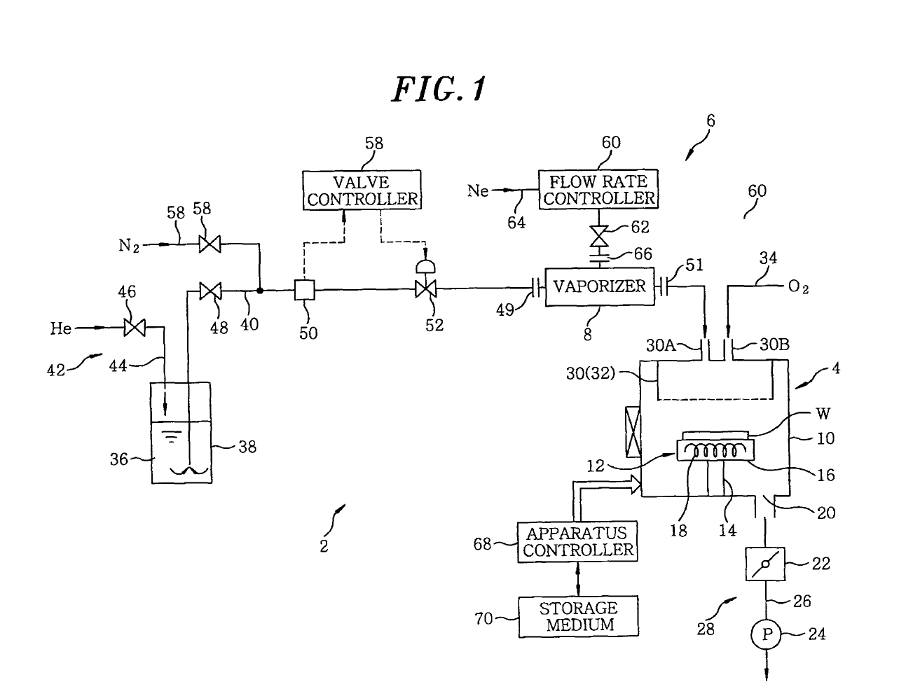

As shown in FIG. 1, a film forming apparatus 2 in accordance with the embodiment of the present invention includes an apparatus main body 4 serving as a gas using system and a material gas supply system 6 for supplying a material gas to the apparatus main body 4. In the apparatus main body 4, a film forming process is performed on a semiconductor wafer W serving as a target object. The material gas supply system 6 includes a vaporizer 8.

First, the apparatus main body 4 will be explained. As shown in FIG. 1, the apparatus main body 4 has a cylindrical processing chamber 10 made of, e.g., an aluminum alloy. A holding unit 12 for holding the semiconductor wafer W serving as a target object is provided in the processing chamber 10. Specifically, the holding unit 12 includes a disc-shaped mounting table 16 supported by a column 14 standing upright at a bottom portion of the processing chamber 10. The wafer W is mounted on the mounting table 16. The mounting table 16 includes therein a heating unit 18 formed of, e.g., a tungsten wire. The wafer W held by the holding unit 12 is heated by the heating unit 18.

As shown in FIG. 1, a gas exhaust port 20 is provided at the bottom portion of the processing chamber 10. The gas exhaust port 20 is connected to a vacuum exhaust system 28 having a gas exhaust path 26. A pressure control valve 22 and a vacuum pump 24 are installed in order in the gas exhaust path 26. The processing chamber 10 is vacuum evacuated by the vacuum exhaust system 28 such that a predetermined depressurized atmosphere can be maintained in the processing chamber 10.

Further, a gas inlet member 32 configured as, e.g., a shower head 30 is provided at a ceiling portion of the processing chamber 10. A material gas supply system 6 and another gas supply system for supplying a desired gas are respectively connected to gas inlets 30A and 30B of the shower head 30. Accordingly, necessary gases are supplied into the processing chamber 10 through the shower head 30. Although two gas inlets are shown in FIG. 1, one gas inlet or three or more gas inlets may be provided depending on the types of gases. Further, the shower head 30 may be configured such that a material gas and a desired gas are mixed in the shower head 30. Alternatively, the shower head 30 may be configured such that different types of gases are individually introduced into the shower head 30 and flowed along the respective paths in the shower head 30 and, then, are mixed in the processing chamber 10.

In this embodiment, there is employed a so-called post-mix method in which a material gas and a desired gas individually flow in the shower head 30 before they are mixed in the processing chamber 10. Further, an oxidizing gas such as O₂ gas is supplied in addition to the material gas and an oxidizing gas supply system 34 is connected to the gas inlet 30B.

Next, the material gas supply system 6 will be explained. First, the material gas supply system 6 includes a liquid material tank 38 storing therein a liquid material 36. For example, PET is used as the liquid material 36. Further, a material path 40 is provided between the liquid material tank 38 and the shower head 30 of the apparatus main body 4 serving as a gas using system. One end of the material path 40 is immersed in the liquid material 36 stored in the liquid material tank 38. The other end of the material path 40 is connected to the gas inlet 30A of the shower head 30. The material path 40 is made of, e.g., stainless steel.

The liquid material tank 38 is provided with a force-feed unit 42 for force-feeding the liquid material 36 to the material path 40. The force-feed unit 42 has a pressure line 44 whose leading end is inserted into an inner cavity portion of the liquid material tank 38 without being immersed in the liquid material 36 stored in the liquid material tank 38. The pressure line 44 is provided with a switching valve 46 for controlling the pressurization. A gas pressurized at a predetermined pressure is supplied into the liquid material tank 38 through the pressure line 44, so that the liquid material 36 in the liquid material tank 38 can be force-fed to the material path 40. For example, a rare gas such as He may be used as the pressurized gas.

The material path 40 is provided with an upstream valve 48, a liquid flowmeter 50, a flow rate control valve 52 and the vaporizer 8 arranged in order from the upstream side to the downstream side. The vaporizer 8 is connected to the material path 40 via path-side connecting members 49 and 51 configured as flanges. A purge gas path 56 provided with a switching valve 54 is connected to the material path 40 between the upstream valve 48 and the liquid flowmeter 50, so that a purge gas can flow in the material path 40 if necessary. For example, N₂ gas or a rare gas such as He and Ar may be used as the purge gas.

The liquid flowmeter 50 measures a flow rate of the liquid material 36 flowing in the material path 40. The flow rate control valve 52 is controlled by a valve controller 58 having, e.g., a computer based on the measurement values obtained by the liquid flowmeter 50. Accordingly, the liquid material 36 can flow at a desired flow rate in the material path 40.

The vaporizer 8 is configured such that the liquid material 36 supplied from the material path 40 is sprayed with a carrier gas and the sprayed liquid material 36 is heated and vaporized to produce a material gas. Accordingly, the vaporizer 8 is connected to a carrier gas pipe 64 provided with a flow rate controller 60 such as a mass flow controller and a switching valve 62. Specifically, the carrier gas pipe 64 is connected to the vaporizer 8 via a pipe-side connecting member 66 configured as a flange. For example, a rare gas such as He and Ar or an inert gas such as N₂ may be used as a carrier gas. Further, if necessary, a tape heater or the like (not shown) for preventing re-liquefaction of the material gas may be provided on the downstream side of the vaporizer 8 in the material path 40. The configuration of the vaporizer 8 will be described in detail later.

The whole operations of the film forming apparatus 2 including the material gas supply system 6 and the apparatus main body 4, e.g., the start/stop of supply of each gas, setting of flow rates, and the start/stop of maintenance, are performed in accordance with instructions of an apparatus controller 68 having, e.g., a computer. Further, programs for executing the instructions are stored in a storage medium 70. The storage medium 70 may be a memory such as a ROM and RAM, a hard disk, a disc-shaped recording medium such as a CD-ROM or the like.

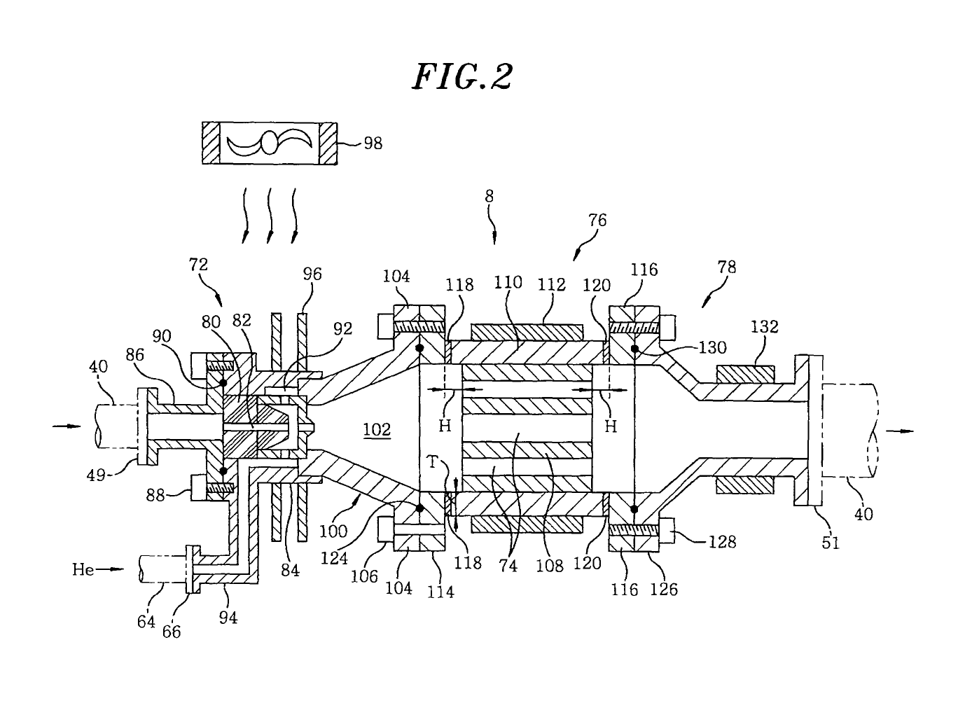

Next, the vaporizer 8 is explained. As shown in FIGS. 2 to 5, the vaporizer 8 includes a nozzle unit 72, a vaporizing unit 76 connected to the nozzle unit 72 and an ejection head (ejection unit) 78 connected to the vaporizing unit 76. The nozzle unit 72 sprays the liquid material supplied thereto in a mist state with a carrier gas to produce a material mist. The vaporizing unit 76 has a plurality of vaporizing paths 74 through which the material mist passes. The vaporizing unit 76 heats and vaporizes the material mist flowing in the vaporizing paths 74 to produce a material gas. The ejection head (ejection unit) 78 ejects the material gas to a subsequent stage.

As shown in FIGS. 2 to 5, the nozzle unit 72 has a nozzle main body 80 made of resin, e.g., Teflon (registered trademark). A fine hole 82 serving as a narrow flow path is formed at the center of the nozzle main body 80. The nozzle main body 80 is contained in a cylindrical nozzle housing 84. A material introduction head 86 is fixed on the upstream side of the nozzle housing 84 via bolts 88. A seal member 90 such as a metal gasket having a high heat resistance is interposed between the nozzle housing 84 and the material introduction head 86 to ensure the airtightness. Further, a front end of the material introduction head 86 and the path-side connecting member 49 of the upstream side of the material path 40 are connected to each other via bolts (not shown).

Further, a ring-shaped carrier gas injection space 92 is formed in the nozzle housing 84 by an annular groove formed at an inner wall of the nozzle housing 84. The carrier gas injection space 92 is arranged to face a leading end portion of the nozzle main body 80. A carrier gas inlet pipe 94 is extended from the carrier gas injection space 92. The carrier gas inlet pipe 94 is connected to the pipe-side connecting member 66 of the carrier gas pipe 64 via bolts (not shown). By this configuration, the carrier gas can be introduced into the nozzle unit 72. Accordingly, the liquid material discharged from the leading end of the nozzle main body 80 after passing through the fine hole 82 of the nozzle main body 80 is converted into a mist with the carrier gas ejected from the carrier gas injection space 92 surrounding the nozzle main body 80, thereby forming the material mist.

Further, a plurality of cooling fins 96 are provided at an outer peripheral surface of the nozzle housing 84. The cooling fins 96 are cooled by using a cooling fan 98. Accordingly, the nozzle main body 80 can be prevented from being heated to a temperature exceeding a decomposition temperature of the liquid material. Further, a cone-shaped diffusion housing 100 having an increasing diameter is coupled to the downstream side of the nozzle housing 84. The material mist is sprayed in the diffusion housing 100 to diffuse in a mist diffusion space 102 of the diffusion housing 100.

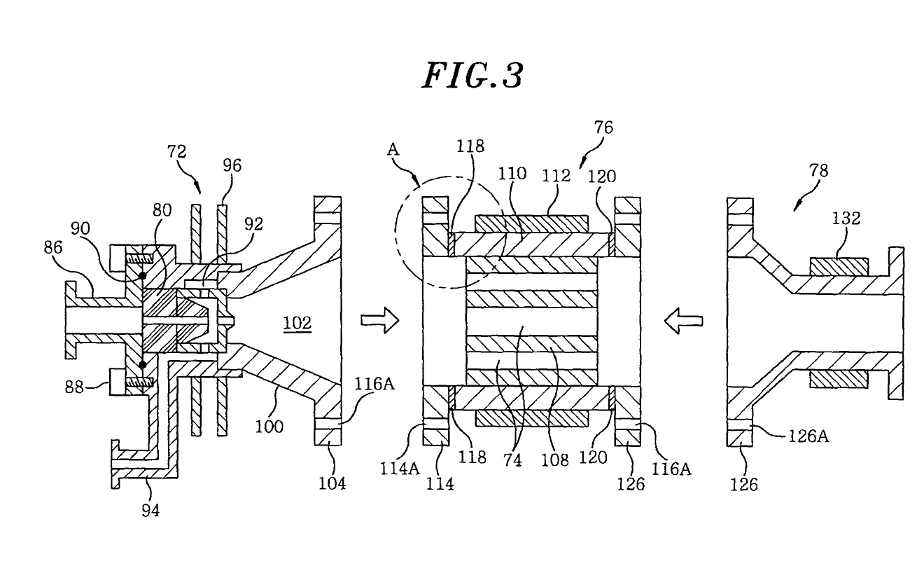

A connecting member 104 configured as a ring-shaped flange is provided at a leading end portion of the diffusion housing 100. The connecting member 104 is connected to the vaporizing unit 76 via bolts 106. In the example shown in FIG. 2, the connecting member 104 is formed integrally with the diffusion housing 100 to form a single body. Bolt holes 104A are circumferentially formed at the connecting member 104 at specific intervals (see FIG. 3).

Main constituent components of the nozzle unit 72 other than the nozzle main body 80 made of resin, i.e., the nozzle housing 84, the material introduction head 86, the bolts 88, the carrier gas inlet pipe 94, the cooling fins 96, the diffusion housing 100, the connecting member 104 and the like, are formed of, e.g., stainless steel. Stainless steel has an excellent stiffness, but has thermal conductivity inferior to other metal materials.

The vaporizing unit 76 includes a vaporizing unit main body 108 in which the vaporizing paths 74 are formed, a main body container 110 containing the vaporizing unit main body 108, a heater 112 for heating the material mist passing through the vaporizing paths 74, and connecting members 114 and 116 provided at both ends of the main body container 110. The main body container 110 is extended further than the vaporizing unit main body 108 in a traveling direction of the material, i.e., along the material path 40. Specifically, as shown in FIGS. 2 and 3, both end sections of the main body container 110 are extended further than corresponding end sections of the vaporizing unit main body 108 along the material path 40.

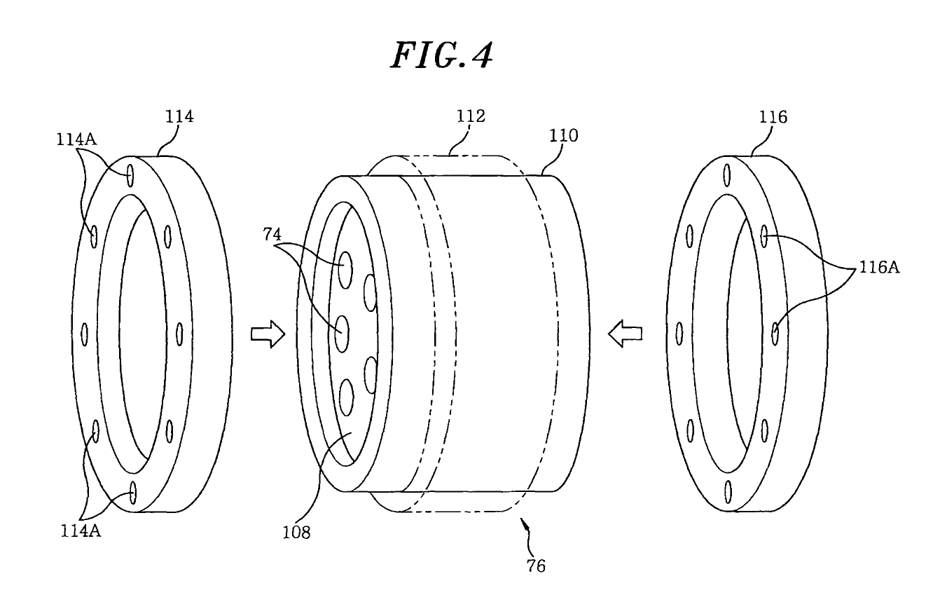

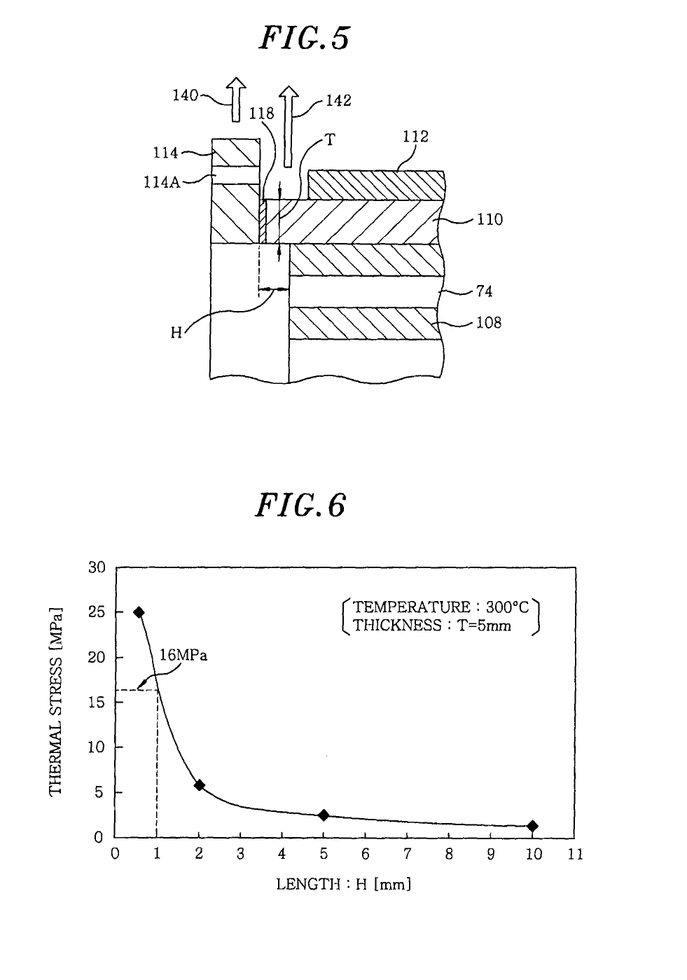

On the whole, as shown in FIG. 4, the vaporizing unit main body 108 is formed in a columnar shape, and vaporizing paths 74 are formed to pass through the vaporizing unit main body 108 in a longitudinal direction thereof. The cylindrical main body container 110 is provided to cover an outer peripheral surface of the columnar vaporizing unit main body 108. Thus, the main body container 110 forms an outer peripheral wall of the vaporizing unit 76. The heater 112 is annularly provided to surround an outer peripheral surface of the main body container 110. As shown in FIG. 5, the both end sections of the main body container 110 are extended by a length H from the end sections of the vaporizing unit main body 108 arranged inside the main body container 110 on the upstream and downstream sides of the material path 40, respectively.

The vaporizing unit main body 108 and the main body container 110 may be separately formed. Then, the columnar vaporizing unit main body 108 is received in the cylindrical main body container 110 and they are joined to each other. Alternatively, the vaporizing unit main body 108 and the main body container 110 may be formed as a single body by machining a large metal block. When the vaporizing unit main body 108 and the main body container 110 are formed as a single body, there is no joint surface between the vaporizing unit main body 108 and the main body container 110. Accordingly, thermal conductivity between the vaporizing unit main body 108 and the main body container 110 is improved, thereby enhancing thermal efficiency. Further, the vaporizing unit main body 108 and the main body container 110 are required to be formed of a metal material having high (excellent) thermal conductivity, e.g., aluminum.

Meanwhile, the two connecting members 114 and 116 are respectively connected to different components forming the material path 40 (the nozzle unit 72 arranged on the upstream side and the ejection head 78 arranged on the downstream side in this embodiment). Accordingly, the connecting members 114 and 116 are required to be formed of a material having excellent stiffness to ensure strong connection. Further, when there is a thermal expansion difference between the connecting members 114 and 116 and the components to be connected thereto (the nozzle unit 72 arranged on the upstream side and the ejection head 78 arranged on the downstream side in this embodiment), leakage of the material occurs due to deformation caused by a thermal stress as described above. Accordingly, the connecting members 114 and 116 are required to be formed of a material having substantially the same linear expansion coefficient as that of a material of the components to be connected thereto (the nozzle unit 72 arranged on the upstream side and the ejection head 78 arranged on the downstream side in this embodiment), preferably, the same material as the material of the components to be connected thereto. Therefore, the connecting members 114 and 116 are formed of the same material as the material of the nozzle unit 72 and the ejection head 78, e.g., stainless steel, which has higher stiffness and lower thermal conductivity than the material (e.g., aluminum) of the vaporizing unit main body 108 and the main body container 110. Further, as shown in FIG. 3, bolt holes 114A and 116A are formed at the connecting members 114 and 116 in a circumferential direction, respectively.

As described above, the material of the main body container 110 is different from the material of the connecting members 114 and 116. Accordingly, the end sections of the main body container 110 are bonded to the connecting members 114 and 116 by explosion bonding. Consequently, explosion bonded joints 118 and 120 are formed between the end sections of the main body container 110 and the connecting members 114 and 116. Further, the explosion bonding (connection) is a press-connecting method using explosion energy, and allows different materials to be strongly bonded to each other.

Further, as shown in FIG. 5, the length H between the end sections of the vaporizing unit main body 108 and the main body container 110 in a direction of the material path 40 is set such that the thermal stress applied to connecting portions of the main body container 110, i.e., the explosion bonded joints 118 and 120 does not exceed a fatigue (failure) limit of the material of the main body container 110 (aluminum in this embodiment) at an allowable maximum temperature of the vaporizer. The term “allowable maximum temperature” used herein denotes a maximum temperature at which the liquid material to be vaporized is not decomposed and deformed, thereby causing no influence on a film forming process.

If the length H is too small compared to a thickness T (see FIG. 5) of the main body container 110, a thermal stress applied to the explosion bonded joints 118 and 120 due to a thermal expansion difference between the main body container 110 and the connecting members 114 and 116 becomes excessively large. Consequently, it may lead to breakage of the explosion bonded joints 118 and 120 on the side of the main body container 110 formed of a material having relatively low stiffness (aluminum). Accordingly, the length H is required to be sufficiently large although it depends on the thickness T. In this case, the length H is set to be equal to or larger than 1 mm.

Further, the connecting member (flange) 104 made of stainless steel in the nozzle unit 72 and the connecting member (flange) 114 made of stainless steel in the vaporizing unit 76 are airtightly connected to each other via a seal member 124 formed of a metal gasket having an excellent heat resistance, by bolts 106.

Further, the ejection head 78 includes a funnel-shaped portion having an inner diameter gradually decreasing toward the downstream side and a straight pipe-shaped portion located on the downstream side of the funnel-shaped portion. The downstream end section of the ejection head 78 is connected to the path-side connecting member 51 arranged on the downstream side of the material path 40 via bolts (not shown). Further, a connecting member 126, which is configured as a ring-shaped flange connected to the vaporizing unit 76 via bolts 128, is provided on the upstream side of the ejection head 78. Bolt holes 126A are circumferentially formed at the connecting member 126 at specific intervals (see FIG. 3).

A seal member 130 formed of a metal gasket having an excellent heat resistance is interposed between the connecting members 116 and 126 to ensure airtightness. The ejection head 78 including the connecting member 126 is formed of the same material as the connecting member 116, i.e., stainless steel. An auxiliary heater 132 is arranged at an outer periphery of the straight pipe-shaped portion of the ejection head 78. The auxiliary heater 132 is provided to prevent re-liquefaction of the material gas produced by vaporization. The material path 40 arranged on the downstream side of the ejection head 78 has an inner diameter larger than that of the material path 40 arranged on the upstream side of the vaporizer 8. Accordingly, the produced material gas can easily pass through the material path 40.

Next, the operation of the film forming apparatus 2 having the above-described configuration will be explained. As shown in FIG. 1, in the apparatus main body 4 of the film forming apparatus 2, the processing chamber 10 is vacuum evacuated by continuously operating the vacuum pump 24 of the vacuum exhaust system 28 such that the processing chamber 10 is maintained at a predetermined pressure. Further, the semiconductor wafer W placed on the mounting table 16 is maintained at a specific temperature by the heating unit 18.

When a film forming process is started, the material gas supply system 6 supplies a material gas to the film forming apparatus 2 as follows. First, the pressurized gas, e.g., He gas, is supplied to the liquid material tank 38 from the force-feed unit 42. Accordingly, a pressure is applied to the inside of the liquid material tank 38 such that the liquid material 36, e.g., PET, in the liquid material tank 38 flows into the material path 40 toward the downstream side. The flow rate of the liquid material flowing toward the downstream side is controlled by the flow rate control valve 52 operated under control of the valve controller 58. Specifically, the flow rate of the liquid material flowing in the material path 40 is measured by the liquid flowmeter 50 and the values measured by the liquid flowmeter 50 are inputted to the valve controller 58. Then, the valve controller 58 controls the flow rate control valve 52 to maintain a predetermined flow rate value.

As described above, the liquid material flows at a predetermined flow rate toward the downstream side. Then, the liquid material is vaporized by the vaporizer 8 arranged on the downstream side to produce a material gas. The material gas flows together with a carrier gas (e.g., He gas) toward the downstream side and, then, is introduced into the processing chamber 10 through the shower head 30 of the apparatus main body 4. The shower head 30 is supplied with an oxidizing gas, e.g., O₂ gas, from the oxidizing gas supply system 34 that is provided separately while the flow rate of the oxidizing gas being controlled. The O₂ gas and the material gas (PET gas) are mixed with each other in the processing chamber 10. Then, a tantalum oxide (Ta₂O₅) film is formed on the wafer W by, e.g., Chemical Vapor Deposition (CVD).

Now, the operation of the vaporizer 8 will be described in detail. In the vaporizer 8, the vaporizing unit main body 108 in which the vaporizing paths are formed is heated in advance via the main body container 110 by the heater 112. Further, the liquid material which has flowed from the upstream side of the material path 40 is introduced into the nozzle unit 72. The liquid material passes through the fine hole 82 of the nozzle main body 80 and is discharged from the leading end portion of the nozzle main body 80. At this time, the carrier gas is injected into the carrier gas injection space 92 from the carrier gas inlet pipe 94. As a result, the carrier gas is emitted to the leading end portion of the nozzle main body 80, and the liquid material is jetted in a mist state by the force of the carrier gas, thereby producing an atomized material mist.

The material mist is diffused in the mist diffusion space 102 and reaches the preheated vaporizing unit 76 of the downstream side. The material mist takes heat from the surfaces of the vaporizing paths 74 while it flows down in the vaporizing paths 74 of the vaporizing unit main body 108 of the vaporizing unit 76. Accordingly, the material mist is vaporized while it flows down in the vaporizing paths 74, thereby producing a material gas. The material gas supplied from the vaporizing unit 76 reaches the preheated ejection head 78 of the downstream side. Then, the material gas discharged from the vaporizer 8 flows down in the material path 40 of the downstream side.

In the vaporizing unit 76, the main body container 110 and the vaporizing unit main body 108 arranged inside the main body container 110 are formed of a material having excellent thermal conductivity, e.g., aluminum. Accordingly, the heat can be efficiently transferred from the heater 112 to the inside of the vaporizing unit main body 108. Thus, the heat supplied from the heater 112 is efficiently transferred to wall surfaces defining the vaporizing paths 74. Consequently, the liquid material can be efficiently vaporized and thermal efficiency can be improved.

Therefore, the vaporizer 8 (vaporizing unit 76) can have a simple and small structure and can supply a large amount of material gas. Particularly, when the main body container 110 and the vaporizing unit main body 108 may be formed as a single body by machining a metal block, thermal conductivity between the vaporizing unit main body 108 and the main body container 110 is increased, thereby further improving thermal efficiency.

Further, the vaporizing unit 76 may have a high temperature of about 300° C. depending on the liquid material used. Accordingly, a thermal expansion difference due to a material difference is generated between the end sections of the main body container 110 and the connecting members 114 and 116. Thus, a large thermal stress is radially applied to the connecting portions, i.e., explosion bonded joints 118 and 120, between the end sections of the main body container 110 and the connecting members 114 and 116.

As described above, however, the length H between the end sections of the vaporizing unit main body 108 and the end sections of the main body container 110 is set to be sufficiently large. Accordingly, the applied thermal stress is sufficiently reduced, and the explosion bonded joints 118 and 120 are able to withstand the thermal stress. Consequently, it is possible to effectively prevent breakage of the explosion bonded joints 118 and 120.

This feature will be described in detail with reference to FIG. 5. Although the connecting member 114 is illustrated in FIG. 5, the following description is also applied to the other connecting member 116. When the vaporizing unit 76 has a high temperature of about 300° C., the connecting member 114 made of stainless steel is slightly thermally expanded in an outward radial direction as indicated by an arrow 140. Meanwhile, the vaporizing unit main body 108 and the main body container 110 made of aluminum having a linear expansion coefficient larger than that of stainless steel are thermally expanded in an outward radial direction by a deformation amount larger than that of the connecting member 114 as indicated by an arrow 142. Such a thermal expansion difference causes a thermal stress to be applied to the explosion bonded joint 118.

However, when the length H is sufficiently large compared to the thickness T of the main body container 110, a portion corresponding to the length H is deformed, thereby reducing the thermal stress. Accordingly, it is possible to prevent breakage of the explosion bonded joint 118 or the aluminum portion corresponding to the length H. Further, when the length H of the portion of the main body container 110 extended from the vaporizing unit main body 108 is too large, the entire length of the vaporizer 8 is also large. Thus, it is preferable that the length H is as small as possible within the range in which the breakage does not occur.

Next, there will be explained investigation results regarding the relationship between the thermal stress and the length H of the end portion of the main body container 110 extended from the end portion of the vaporizing unit main body 108. FIG. 6 is a graph showing the relationship between the thermal stress and the length H of the end portion of the main body container extended from the end portion of the vaporizing unit main body. In the graph of FIG. 6, a horizontal axis represents the length H [mm], and a vertical axis represents the thermal stress [MPa]. In this investigation, the temperature of the vaporizer was set to be an allowable maximum temperature of 300° C. and the thickness T of the cylindrical main body container 110 was set to be 5 mm. Further, the outer diameter of the vaporizing unit 76 was set to be about 60 mm; the length of the vaporizing unit 76, about 100 mm; and the inner diameter of the vaporizing paths 74, about 4 mm.

As shown in FIG. 6, when the length H is small, e.g., about 0.5 mm, the thermal stress is very large, i.e., about 25 MPa. Meanwhile, as the length H is increased from 0.5 mm, the thermal stress becomes sharply reduced. When the length H is about 3 to 4 mm, the thermal stress becomes very small, i.e., 3 to 2 MPa. When the length H exceeds about 4 mm, the thermal stress slightly changes and converges to zero as the length H increases.

When materials having different thermal expansion coefficients are bonded to each other, the thermal stress is generated by distortion between the different materials due to a thermal expansion difference when the materials are heated. Further, when the thermal stress exceeds the proof stress of one having lower stiffness of the two bonded materials, the lower stiffness material (aluminum) is broken. Further, taking into consideration fatigue of metal due to repeated thermal expansion and contraction of a metal material, the generated thermal stress is required to be equal to or less than twenty percent (20%) of the proof stress of the metal material. For example, the proof stress of aluminum is about 80 MPa and, thus, the fatigue limit of aluminum is set to be 16 MPa, which is 20% of the proof stress of aluminum. Accordingly, in a case where the vaporizer 8 is formed of aluminum and stainless steel, the length H is required to be equal to or more than 1 mm in consideration of the investigation results of FIG. 6 such that the thermal stress generated at the joint is equal to or less than 16 MPa.

In other words, the length H is preferably set to satisfy the following equation:

H≧0.2·T.

As described above, the allowable maximum temperature varies according to the kind of the liquid material 36 used. Further, the thermal stress generated at the joints 118 and 120 varies according not only to the length H of the portion of the main body container 110 extended from the vaporizing unit main body 108 but also to the thickness T thereof. In any case, the length H is set such that, when the vaporizer 8 is formed of materials having different thermal expansion coefficients, the thermal stress generated at the joint is equal to or less than a fatigue limit of the lower stiffness material. In this embodiment, the length H is set such that the thermal stress generated at the joint is equal to or less than 16 MPa, which is a fatigue limit of aluminum.

In accordance with the embodiment of the present invention, a material having high thermal conductivity such as aluminum is used as one of constituent materials and is boned to a different material by explosion bonding. Accordingly, it is possible to provide the vaporizer 8 (vaporizing unit 76) having a simple structure with improved thermal efficiency. Thus, it is possible to supply a large amount of material gas without increasing the size of the vaporizer 8 (vaporizing unit 76).

Further, the cooling fins 96 facilitate cooling of the nozzle unit 72 to thereby effectively prevent thermal decomposition of the liquid material in the nozzle unit 72.

Further, although aluminum is used as a constituent material of the vaporizing unit main body 108 and the main body container 110 in the above embodiment, the present invention is not limited thereto. The vaporizing unit main body 108 or the main body container 110 may be formed of one material selected from a group consisting of aluminum, an aluminum alloy and nickel.

Further, although stainless steel is used as a constituent material of the connecting members 114 and 116 in the above embodiment, the present invention is not limited thereto. The connecting member 114 or 116 may be formed of one material selected from a group consisting of stainless steel and a Ni alloy such as Hastelloy (registered trademark).

Further, although stainless steel is used as a constituent material of the nozzle unit 72 and the ejection head 78 in the above embodiment, the present invention is not limited thereto. The nozzle unit 72 or the ejection head 78 may be formed of one material selected from a group consisting of stainless steel and a Ni alloy such as Hastelloy (registered trademark).

Further, although a single-wafer type main body is used as the apparatus main body 4 in the above embodiment, the present invention is not limited thereto. A batch type main body in which a plurality of target objects is simultaneously processed may be used as the apparatus main body 4.

Further, although PET is used as a liquid material in the above embodiment, the present invention is not limited thereto. The liquid material may be one material selected from a group consisting of pentaethoxy tantalum (PET), a metal liquid material for forming a PZT film (an oxide film including Pb, Zr and Ti), a BST film (an oxide film including Ba, Sr and Ti) or the like, Cu(EDMDD)₂, tetraethoxysilane (TEOS), copper hexafluoroacetylacetonate trimethylvinylsilane (Cu(hfac)TMVS), trimethyl aluminum (TMA), tert-butylimidotris(diethylamido)tantalum (TBTDET), titanium tetrachloride (TiCl₄), tetramethylsilane (TMS), and tetrakisethoxy hafnium (TEH).

Further, although He is used as a pressurized gas or carrier gas in the above embodiment, the present invention is not limited thereto. Another rare gas such as Ar and Ne, N₂ gas or the like may be used as the pressurized gas or carrier gas.

Further, although a semiconductor wafer is exemplified as a target object in the above embodiment, the present invention is not limited thereto. That is, the present invention can be applied to a glass substrate, an LCD substrate, a ceramic substrate and the like.

What is claimed is:

1. A vaporizer comprising:
a nozzle unit for spraying a liquid material supplied thereto in a mist state with a carrier gas to produce a material mist;
a vaporizing unit connected to the nozzle unit and having a plurality of vaporizing paths through which the material mist passes to heat and vaporize the material mist to produce a material gas; and
an ejection unit connected to the vaporizing unit to eject the material gas to a subsequent stage,
wherein the vaporizing unit includes:
a vaporizing unit main body in which the vaporizing paths are formed;
a main body container containing the vaporizing unit main body, both end sections of the main body container being extended further than the vaporizing unit main body;
a heater for heating the material mist passing through the vaporizing paths; and
connecting members provided at the both end sections of the main body container to connect the vaporizing unit with the nozzle unit and the ejection unit,
wherein the vaporizing unit main body and the main body container are formed of a material different from a material of the connecting members, where the material of the vaporizing unit main body and the main body container has thermal conductivity higher than that of the connecting members, and
wherein the end sections of the main body container are bonded to the connecting members by explosion bonding.

2. The vaporizer of claim 1, wherein the main body container and the vaporizing unit main body are formed as a single body by machining.

3. The vaporizer of claim 1, wherein a length of each of the end sections of the main body container extended from the vaporizing unit main body is set such that a thermal stress applied to each of the end sections is equal to or less than a fatigue limit of the material of the main body container at an allowable maximum temperature.

4. The vaporizer of claim 3, wherein the allowable maximum temperature is 300° C.

5. The vaporizer of claim 3, wherein the fatigue limit is twenty percent (20%) of a proof stress of the material of the main body container.

6. The vaporizer of claim 1, wherein the material of the vaporizing unit main body and the main body container is one material selected from a group consisting of aluminum, an aluminum alloy and nickel, and
wherein the material of the connecting members is stainless steel or a Ni alloy.

7. The vaporizer of claim 1, wherein a material of the nozzle unit and the ejection unit is stainless steel or a Ni alloy.

8. The vaporizer of claim 1, wherein the liquid material is one material selected from a group consisting of pentaethoxy tantalum (PET), a metal liquid material for forming a PZT film (an oxide film including Pb, Zr and Ti) or a BST film (an oxide film including Ba, Sr and Ti), Cu(EDMDD)₂, tetraethoxysilane (TEOS), copper hexafluoroacetylacetonate trimethylvinylsilane (Cu(hfac)TMVS), trimethyl aluminum (TMA), tert-butylimidotris(diethylamido)tantalum (TBTDET), titanium tetrachloride (TiCl₄), tetramethylsilane (TMS), and tetrakisethoxy hafnium (TEH).

9. A material gas supply system for supplying a material gas to a gas using system, comprising:
a liquid material tank storing therein a liquid material;
a material path whose one end is connected to the liquid material tank and whose other end is connected to the gas using system;
a force-feed unit provided to the liquid material tank to force-feed the liquid material to the material path with a pressurized gas; and
the vaporizer described in any one of claims 1 to 8, the vaporizer being installed in the material path to vaporize the liquid material to produce a material gas.

10. A film forming apparatus for performing a film forming process on a target object, comprising:
a vacuum evacuable processing chamber;
a holding unit for holding the target object in the processing chamber;
a heating unit for heating the target object;
a gas inlet member for introducing a gas into the processing chamber; and
the material gas supply system described in claim 9 and connected to the gas inlet member.

11. A vaporizing unit for vaporizing a material mist to produce a material gas, comprising:
a vaporizing unit main body in which the vaporizing paths are formed, the material mist passing through the vaporizing paths,
a main body container containing the vaporizing unit main body,
a heater for heating the material mist passing through the vaporizing paths,
connecting members provided at both end sections of the main body container to connect the vaporizing unit with a component provided at upstream or downstream side of the vaporizing unit,
wherein the vaporizing unit main body and the main body container are formed of a material different from a material of the connecting members, where the material of the vaporizing unit main body and the main body container has thermal conductivity higher than that of the connecting members, and
wherein the end sections of the main body container are bonded to the connecting members by explosion bonding.

12. The vaporizing unit of claim 11, wherein the main body container and the vaporizing unit main body are formed as a single body by machining.

13. The vaporizing unit of claim 11, wherein the both end sections of the main body container are extended further than the vaporizing unit main body, and
wherein a length of each of the end sections of the main body container extended from the vaporizing unit main body is set such that a thermal stress applied to each of the end sections is equal to or less than a fatigue limit of the material of the main body container at an allowable maximum temperature.

14. The vaporizing unit of claim 13, wherein the allowable maximum temperature is 300° C.

15. The vaporizing unit of claim 13, wherein the fatigue limit is twenty percent (20%) of a proof stress of the material of the main body container.

16. The vaporizing unit of claim 11, wherein the material of the vaporizing unit main body and the main body container is one material selected from a group consisting of aluminum, an aluminum alloy and nickel, and
wherein the material of the connecting members is stainless steel or a Ni alloy.

17. The vaporizing unit of claim 11, wherein a material of the component provided at the upstream or downstream side of the vaporizing unit is stainless steel or a Ni alloy.
